(19) United States
(12) Patent Application Publication
(10) Pub. No.: US 2014/0183720 A1
(43) Pub. Date: Jul. 3, 2014

(54) METHODS OF MANUFACTURING INTEGRATED CIRCUITS HAVING A COMPRESSIVE NITRIDE LAYER

(71) Applicants: GLOBALFOUNDRIES INC., Grand Cayman (KY); INTERNATIONAL BUSINESS MACHINES CORPORATION, Armonk, NY (US)

(72) Inventors: Scott Beasor, Rhinebeck, NY (US); Jay Strane, Wappingers Falls, NY (US); Man Fai Ng, Poughkeepsie, NY (US); Brett H. Engel, Hopewell Jct, NY (US); Chang Yong Xiao, Wappingers Falls, NY (US); Michael P. Belyansky, Bethel, CT (US); Tsung-Liang Chen, Lagrangeville, NY (US); Kyung Bum Koo, Fishkill, NY (US)

(73) Assignees: INTERNATIONAL BUSINESS MACHINES CORPORATION, Armonk, NY (US); GLOBALFOUNDRIES INC., Grand Cayman (KY)

(21) Appl. No.: 13/731,305

(22) Filed: Dec. 31, 2012

(51) Int. Cl. H01L 21/768; H01L 23/48

(52) U.S. Cl. CPC H01L 21/76838; H01L 23/48
USPC 257/734; 438/688

(57) ABSTRACT

Methods of manufacturing semiconductor integrated circuits having a compressive nitride layer are disclosed. In one example, a method of fabricating an integrated circuit includes depositing an aluminum layer over a semiconductor substrate, depositing a tensile silicon nitride layer or a neutral silicon nitride layer over the aluminum layer, and depositing a compressive silicon nitride layer over the tensile silicon nitride layer or the neutral silicon nitride layer. The compressive silicon nitride layer is deposited at a thickness that is at least about twice a thickness of the tensile silicon nitride layer or the neutral silicon nitride layer. Further, there is no delamination present at an interface between the aluminum layer and the tensile silicon nitride layer or the neutral silicon nitride layer, or at an interface between tensile silicon nitride layer or the neutral silicon nitride layer and the compressive nitride layer.

### TECHNICAL FIELD

The present invention generally relates to methods for fabricating semiconductor devices, and more particularly relates to methods of manufacturing semiconductor integrated circuits having a compressive nitride layer disposed over a metal layer.

### BACKGROUND

Modern integrated circuits typically include multiple layers of conductive lines separated by dielectric layers. These layers of conductive lines are typically referred to as metal layers (e.g., metal 1, metal 2, metal 3, etc.) and the dielectric layers are typically referred to as interlevel dielectric layers (ILD0, ILD1, ILD2, etc.). Aluminum lined films are commonly used as metal layers due to their resistivity and resistance to electromigration. Other suitable metals include copper, or aluminum doped with copper, for example.

Generally, barrier layers are utilized with aluminum containing conductive structures to prevent aluminum diffusion into silicon substrates and insulative layers. Aluminum diffusion into silicon substrate degrades device integrity as well as the aluminum structure. Similarly, aluminum diffusion into insulative structures degrades performance of the insulative layers, as well as the aluminum structure.

Conventionally, barrier layers, such as silicon nitride, and in particular compressive silicon nitride, have been utilized between the aluminum structure and the substrate and insulative layer. However, the interface between the silicon nitride material and the aluminum structure can be poor if the silicon nitride material is not processed properly. For example, chemical vapor deposited (CVD) silicon nitride may result in a poor aluminum layer/silicon nitride layer interface and possible delamination of the aluminum from the silicon nitride. With exemplary reference to FIG. 1, a cross-sectional view of a portion of an integrated circuit 100 is shown having a metal layer 101, a compressive nitride layer 103, wherein numeral 102 indicates the interface between metal layer 101 and compressive nitride layer 103. As shown, a delamination region 110 detrimentally causes a void space along the interface 102, and further causes a surface irregularity 111 on an upper surface of the compressive nitride layer 103. Delamination detrimentally creates a path from which aluminum ions can diffuse outward and to which moisture and other contaminates can diffuse inward.

Accordingly, it is desirable to provide improved methods of manufacturing semiconductor integrated circuits having silicon nitride layers. Particularly, it is desirable to provide improved methods that reduce the incidence of aluminum layer/silicon nitride layer delamination. Furthermore, other desirable features and characteristics of the present invention will become apparent from the subsequent detailed description of the invention and the appended claims, taken in conjunction with the accompanying drawings, the brief summary, and this background of the invention.

### BRIEF SUMMARY

Methods of manufacturing semiconductor integrated circuits having a compressive nitride layer disposed over a metal layer are disclosed herein. In accordance with an exemplary embodiment, a method of fabricating an integrated circuit includes a method of fabricating an integrated circuit includes depositing an adhesion layer over a metal layer and depositing a compressive nitride layer over the adhesion layer.

In accordance with another exemplary embodiment, an integrated circuit includes a semiconductor substrate, a metal layer disposed over the semiconductor substrate, an adhesion layer disposed over the metal layer, and a compressive nitride layer disposed over the adhesion layer.

In accordance with yet another exemplary embodiment, a method of fabricating an integrated circuit includes depositing an aluminum layer over a semiconductor substrate, depositing a tensile silicon nitride layer or a neutral silicon nitride layer over the aluminum layer, and depositing a compressive silicon nitride layer over the tensile silicon nitride layer or the neutral silicon nitride layer. The compressive silicon nitride layer is deposited at a thickness that is at least about twice a thickness of the tensile silicon nitride layer or the neutral silicon nitride layer. Further, there is no delamination present at an interface between the aluminum layer and the tensile silicon nitride layer or the neutral silicon nitride layer, or at an interface between tensile silicon nitride layer or the neutral silicon nitride layer and the compressive nitride layer.

This brief summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

### BRIEF DESCRIPTION OF THE DRAWINGS

The present invention will hereinafter be described in conjunction with the following drawing figures, wherein like numerals denote like elements, and wherein:

FIG. 1 illustrates a cross sectional view of an aluminum layer/silicon nitride layer interface with delamination;

FIG. 2 illustrates a method for fabricating an integrated circuit with a compressive silicon nitride layer in accordance with one embodiment; and

FIG. 3 shows a series of 100× magnified optical images of integrated circuits with compressive nitride liners illustrating the benefits of the present invention.

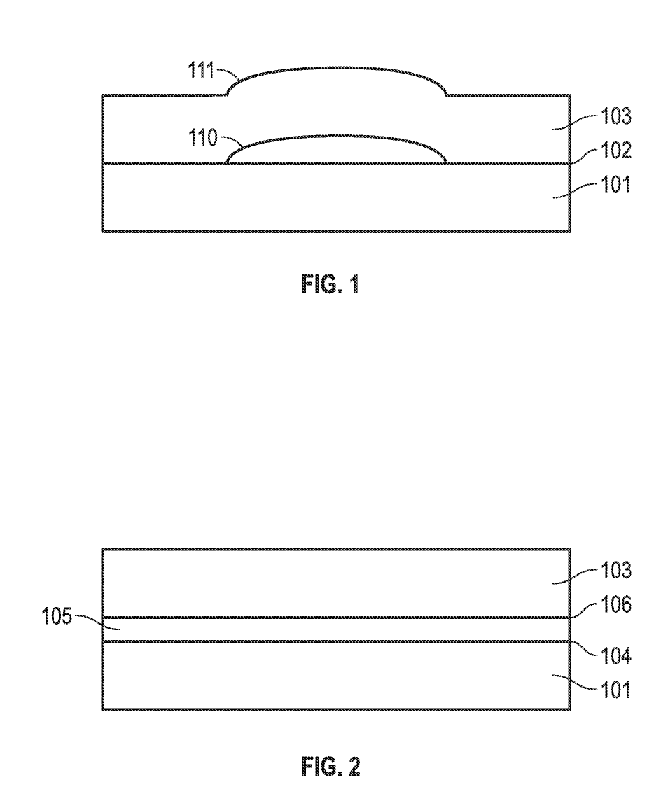

### DETAILED DESCRIPTION

The following detailed description is merely exemplary in nature and is not intended to limit the invention or the application and uses of the invention. As used herein, the word “exemplary” means “serving as an example, instance, or illustration.” Thus, any embodiment described herein as “exemplary” is not necessarily to be construed as preferred or advantageous over other embodiments. All of the embodiments described herein are exemplary embodiments provided to enable persons skilled in the art to make or use the invention and not to limit the scope of the invention which is defined by the claims. Furthermore, there is no intention to be bound by any expressed or implied theory presented in the preceding technical field, background, brief summary, or the following detailed description.

Embodiments of the present disclosure are generally directed to methods of manufacturing semiconductor integrated circuits having a compressive nitride layer, for example a compressive silicon nitride layer, disposed over a metal layer, for example an aluminum layer. Broadly speaking, in one embodiment, a method for manufacturing an integrated circuit in accordance with the present disclosure include depositing a metal layer, such as aluminum, over a semiconductor substrate. Thereafter, an adhesive layer is deposited over the metal layer. The adhesive layer serves to provide improved adhesion between the metal layer and the nitride layer, so as to overcome the difficulties encountered in the prior art such as delamination. The adhesive layer can include, for example, a tensile nitride layer or a neutral (i.e., “unstrained”) nitride layer, such as a tensile silicon nitride layer or a neutral silicon nitride layer. The adhesive layer is deposited as thinly as possible, as will be described in greater detail below. Thereafter, a layer of a compressive nitride, such as a compressive silicon nitride, is deposited over the adhesion layer. The thickness of the compressive nitride layer is at least two times greater than the thickness of the adhesion layer.

Beneficially, it has been discovered by the inventors herein that tensile and neutral nitride layers do not exhibit delamination when applied to a metal layer, such as aluminum, as do compressive nitride layers. However, tensile and neutral nitride layers do not allow for as precise etching of the underlying metal layer, during subsequent etching steps in the integrated circuit manufacturing process, as compressive nitride layers. By depositing a thin tensile or compressive nitride layer as an adhesion layer over the metal layer first before depositing the compressive nitride layer, it has been discovered that delamination may be avoided, while retaining all or most of the beneficial etching characteristics exhibited by a compressive nitride layer disposed directly over a metal layer.

Reference is now made to FIG. 2, which shows a cross-sectional view of a portion of an integrated circuit 200 that illustrates a method for manufacturing an integrated circuit in accordance with an embodiment of the present disclosure. Disposed (either directly or indirectly) over a semiconductor substrate (not shown) is a metal layer 101, such as an aluminum layer. The term semiconductor substrate, as used herein, refers broadly to the class of substrates suitable for use in integrated circuit manufacturing, including for example silicon substrates, silicon germanium substrates, silicon-on-insulator substrates, and others as are well-known in the art.

In an embodiment, the metal layer 101, such as aluminum, may be deposited over the semiconductor substrate (not shown) through physical vapor deposition (PVD), for example by sputtering, or any other known method. Sputtering may be described as a series of four steps: 1) high-energy ions are generated and are used to bombard a target (the source of material for deposition); 2) the ions sputter (eject) atoms from the target; 3) the sputtered atoms reach the substrate; and 4) the sputtered atoms condense and form a thin film over the substrate.

With continued reference to FIG. 2, disposed over the metal layer 101 is an adhesion layer 105. The adhesion layer may include, for example, a tensile or a neutral nitride, such as a tensile or neutral silicon nitride. Reference numeral 104 points to the interface between the metal layer 101 and the adhesion layer 105. As shown, there is no delamination between the metal layer 101 and the adhesion layer 105, for example there would be no delamination between an aluminum layer and a tensile or compressive silicon nitride layer.

As is known in the art, strain inducing nitrides, such as silicon nitrides, may be deposited by chemical vapor deposition (CVD). The magnitude of strain and the type of strain induced (compressive, tensile, or neutral) is well controlled with the CVD of silicon nitride by modulating the deposition conditions, especially temperature. As such, the same manufacturing tool can be used in the manufacturing process to deposit silicon nitride as compressive, tensile, or neutral.

Continued reference is made to FIG. 2, wherein, in a further process step, a compressive nitride layer 103, such as a compressive silicon nitride, is disposed over the adhesion layer 105. Again, CVD is one suitable example for the deposition of compressive nitride layer 103. Reference numeral 106 indicates the interface between the adhesion layer 105 and the compressive nitride layer 103. As shown, there is observed to be no delamination at the adhesion layer/compressive nitride layer interface 106. As such, there is no delamination observed at all in the integrated circuit 200.

As illustrated, the compressive nitride layer 103 is substantially thicker than the adhesion layer 105. In one embodiment, the compressive nitride layer 103 may be at least twice as thick as the adhesion layer 105. In another embodiment, the compressive nitride layer 103 may be at least three times as thick as the adhesion layer 105. For example, the adhesion layer 105 can be about 20 Å to about 80 Å in thickness, and the compressive nitride layer 103 can be about 40 Å to about 160 Å in thickness. In some embodiments, it has been found beneficial to deposit a tensile nitride adhesion layer to at least about 20 Å, and a neutral nitride layer to at least about 70 Å. While these embodiments are exemplary, it will be appreciated that the adhesion layer 105 should be made as thin as possible relative to the compressive nitride layer 103, so as to minimize the detrimental effects that the adhesion layer 105 produces during subsequent etching processes, as noted above. However, it has been determined by experimentation that when the compressive nitride layer 103 is at least twice as thick as the adhesion layer 103, the detrimental effects on subsequent etching processes are minimized or are negligible.

Thereafter, further processing steps can be performed to complete the fabrication of the integrated circuit, as are well-known in the art. Further steps conventionally include, for example, the etching of the gate structures and the formation of contacts, among many others. The subject matter disclosed herein is not intended to exclude any subsequent processing steps to form and test the completed integrated circuit as are known in the art.

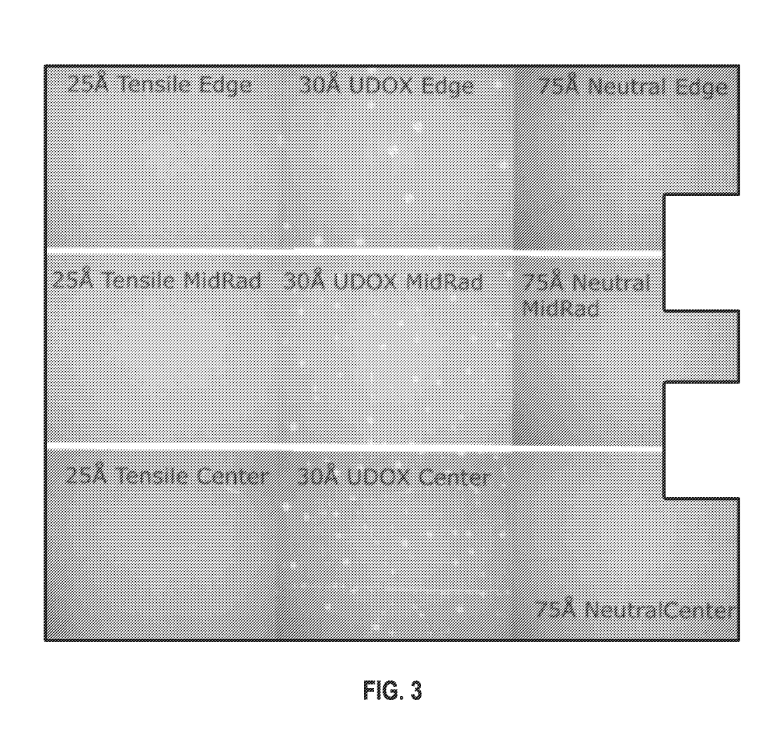

FIG. 3 shows a series of 100× magnified optical images of integrated circuits with compressive nitride liners illustrating the benefits of the present invention. The leftmost series of images shows an integrated circuit (with the three images taken at an edge, mid-radius, and center of the integrated circuit, respectively) with a 25 Å in thickness tensile nitride adhesion layer disposed between the metal layer and the compressive nitride layer. As shown, there is no delamination present in any of the images. The rightmost series of images shows an integrated circuit (with the three images taken at an edge, mid-radius, and center of the integrated circuit, respectively) with a 75 Å in thickness neutral nitride adhesion layer disposed between the metal layer and the compressive nitride layer. As shown, there is no delamination present in any of the images. In contrast, the center series of images shows an integrated circuit (with the three images taken at an edge, mid-radius, and center of the integrated circuit, respectively) with a 50 Å in thickness un-doped silicon oxide (“UDOX”) adhesion layer disposed between the metal layer and the compressive nitride layer. As shown, there is significant delamination present in all of the images—the delamination areas are the lighter shaded circles or “dots.”

As such, embodiments of the present disclosure beneficially allow for the deposition of a compressive nitride layer, such as a compressive silicon nitride layer, over a metal layer, such as an aluminum layer, without the appearance of delamination as was previously encountered in the art. Minimizing the thickness of the adhesion layer, such as a tensile or neutral nitride layer, allows the beneficial etching properties of a compressive nitride layer disposed over the metal layer to remain substantially untarnished, while eliminating the presence of delamination, which, as noted above, detrimentally creates a path from which aluminum ions can diffuse outward and to which moisture and other contaminates can diffuse inward.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope as set forth in the appended claims and their legal equivalents.

What is claimed is:

1. A method of fabricating an integrated circuit comprising:
depositing an adhesion layer over a metal layer; and
depositing a compressive nitride layer over the adhesion layer.

2. The method of claim 1, further comprising depositing the metal layer over a semiconductor substrate.

3. The method of claim 1, wherein depositing the adhesion layer comprises depositing a tensile nitride.

4. The method of claim 3, wherein depositing the tensile nitride comprises depositing a tensile silicon nitride.

5. The method of claim 4, wherein depositing the adhesion layer comprises depositing the adhesion layer at a thickness of at least about 20 Å.

6. The method of claim 1, wherein depositing the adhesion layer comprises depositing a neutral nitride.

7. The method of claim 6, wherein depositing the neutral nitride comprises depositing a neutral silicon nitride.

8. The method of claim 7, wherein depositing the adhesion layer comprises depositing the adhesion layer at a thickness of at least about 70 Å.

9. The method of claim 1, wherein depositing the compressive nitride layer comprises depositing a compressive nitride layer at a thickness that is at least about twice a thickness of the adhesion layer.

10. The method of claim 9, wherein depositing the compressive nitride layer comprises depositing a compressive nitride layer at a thickness that is at least about three times a thickness of the adhesion layer.

11. The method of claim 1, wherein depositing the compressive nitride layer comprises depositing silicon nitride.

12. The method of claim 1, wherein depositing both the adhesion layer and the compressive nitride layer comprises depositing using chemical vapor deposition.

13. The method of claim 1, wherein depositing the adhesion layer over the metal layer comprises depositing the adhesion layer over aluminum.

14. An integrated circuit comprising:
a semiconductor substrate;
a metal layer disposed over the semiconductor substrate;
an adhesion layer disposed over the metal layer; and
a compressive nitride layer disposed over the adhesion layer.

15. The integrated circuit of claim 14, wherein the metal layer is an aluminum layer.

16. The integrated circuit of claim 14, wherein the adhesion layer is a tensile or a neutral silicon nitride.

17. The integrated circuit of claim 14, wherein the compressive nitride layer is a compressive silicon nitride.

18. The integrated circuit of claim 14, wherein the compressive nitride layer is at least about twice as thick as the adhesion layer.

19. The integrated circuit of claim 14, wherein there is no delamination present at an interface between the metal layer and the adhesion layer or at an interface between the adhesion layer and the compressive nitride layer.

20. A method of fabricating an integrated circuit comprising:
depositing an aluminum layer over a semiconductor substrate;
depositing a tensile silicon nitride layer or a neutral silicon nitride layer over the aluminum layer; and
depositing a compressive silicon nitride layer over the tensile silicon nitride layer or the neutral silicon nitride layer,
wherein the compressive silicon nitride layer is deposited at a thickness that is at least about twice a thickness of the tensile silicon nitride layer or the neutral silicon nitride layer, and
wherein there is no delamination present at an interface between the aluminum layer and the tensile silicon nitride layer or the neutral silicon nitride layer, or at an interface between tensile silicon nitride layer or the neutral silicon nitride layer and the compressive nitride layer.
